(19) United States
(12) Patent Application Publication
(10) Pub. No.: US 2011/0170268 A1
(43) Pub. Date: Jul. 14, 2011

(54) ELECTROMAGNETIC BAND GAP STRUCTURE, ELEMENT, SUBSTRATE, MODULE, AND SEMICONDUCTOR DEVICE INCLUDING ELECTROMAGNETIC BAND GAP STRUCTURE, AND PRODUCTION METHODS THEREOF

(75) Inventors: Koichi Takemura, Tokyo (JP); Noriaki Ando, Tokyo (JP); Tsuneo Tsukagoshi, Tokyo (JP)

(73) Assignee: NEC CORPORATION, Tokyo (JP)

(21) Appl. No.: 13/119,247

(22) PCT Filed: Oct. 2, 2009
(86) PCT No.: PCT/JP2009/005110

§ 371 Date: Mar. 16, 2011

(30) Foreign Application Priority Data
Oct. 2, 2008 (JP) 2008-256970

(51) Int. Cl. H05K 1/16; H01P 1/203; H01Q 1/38; H05K 3/10

(52) U.S. Cl. 361/748; 174/250; 174/258; 174/257; 333/204; 343/700 MS; 29/846

(57) ABSTRACT

To provide a small-sized and thin electromagnetic band gap structure which can be surface-mounted or built in a substrate. An electromagnetic band gap structure according to an aspect of the present invention includes: an insulating substrate; a plurality of conductor pieces regularly arranged on the insulating substrate; a dielectric layer formed so as to fill a space between adjacent ones of the conductor pieces; an interlayer insulating layer formed on the dielectric layer; and a conductor plane which is formed on the interlayer insulating layer and is connected to each of the conductor pieces with a conductor penetrating through the interlayer insulating layer.

### TECHNICAL FIELD

The present invention relates to an electromagnetic band gap (hereinafter EBG) structure having a band gap in a certain frequency band, a filter element, an antenna element, a substrate with a built-in element, a multi-chip module, a semiconductor device, and production methods thereof.

### BACKGROUND ART

An EBG structure is a structure in which dielectric materials or conductors are regularly arranged two-dimensionally or three-dimensionally and which defines a frequency range called a band gap that suppresses or greatly attenuates the propagation of electromagnetic waves in a certain frequency band. In recent years, antennas, noise filters, and the like utilizing the features of the EBG structure have been proposed.

As a specific example of the EBG structure, Patent Literatures 1 to 4 and Non Patent Literature 1 disclose a structure in which pin-like conductor elements each composed of a polygonal plate-like conductor piece and a conductor post are arranged at intervals on a conductor plane and the conductor elements are each connected to the conductor plane. The structure can be regarded as a distributed constant circuit in which a capacitance (C) between the conductor pieces and an inductance (L) constituted by the conductor elements and the conductor plane are two-dimensionally arranged. It is known that such an EBG structure defines a band gap in a frequency range in the vicinity of 1/\sqrt{LC}. Thus, the function of suppressing the propagation of radio waves in a desired frequency range can be exerted by appropriately designing the shape or array of the conductor elements.

Further, Patent Literatures 1 and 2 and Non Patent Literature 1 disclose not only a structure in which a gap between adjacent conductor pieces is used as a capacitance element, but also a structure in which conductor pieces are arranged in two layers and the two-layered conductor pieces are used as a capacitance element, and a structure in which a high-dielectric-constant layer is filled between different layers of the conductor pieces. These EBG structures are produced by stacking a dielectric sheet and conductor pieces on a metal sheet.

In order to expand the application field of such an EBG structure to cellular phones, digital home appliances, information equipment, and the like, it is necessary to downsize the EBG structure so as to achieve high-density mounting. Moreover, it is desired that the frequency band of a band gap can be controlled over a wide range. The frequency at which the band gap of the EBG structure is exhibited is represented by the above-mentioned resonant frequency. Accordingly, in terms of capacitance, the band gap is exhibited at a lower frequency, as the capacitance increases.

### Citation List

### Patent Literature

### [Patent Literature 1] Published Japanese Translation of PCT International Publication for Patent Application, No. 2002-510886

[Patent Literature 2] Published Japanese Translation of PCT International Publication for Patent Application, No. 2005-538629

[Patent Literature 3] Specification of U.S. Pat. No. 6,262,495 B1
[Patent Literature 4] Specification of U.S. Pat. No. 6,483,481 B1

### Non Patent Literature

[Non Patent Literature 1] D. Sievenpiper et al., “IEEE Trans. Microwave Theory and Techniques”, vol. 47, 1999, p. 2059

### SUMMARY OF INVENTION

### Technical Problem

However, when the above-mentioned EBG structure is produced using printed wiring board processes based on sheet stacking and these stacked materials, it is necessary that conductor pieces each have a size of mm□ and that the EBG structure have an overall size of several cm□.

In order to achieve downsizing by increasing the capacitance of the capacitance element or by increasing the capacitance per unit area, the interval between electrodes may be reduced, or a high-dielectric-constant material may be used as the dielectric material between the electrodes. However, a method of stacking sheets which can be handled singly requires a sheet thickness of several 10 μm or more.

Furthermore, as an example of the high-dielectric-constant material, metal oxide materials having a relative permittivity of several tens or more are known. In order to stack sheet-like materials which can be handled singly, however, a compound dispersed in a resin having a small relative permittivity is required, and the effective relative permittivity is at most 20 to 30. Even in the case of parallel plate electrodes, for example, the capacitance generated between the electrodes is at most several pF per 1 mm² when these materials are used.

When such high-dielectric-constant materials are directly formed on a printed wiring board without being mixed with a resin, a thin film formation process in which deposition and reaction/burning are carried out at the same time may be employed. However, since conductor and resin used in printed wiring boards have a low heat resistance, the process temperature is limited to be lower than 200° C. Consequently, the materials contain a number of defects; the relative permittivity is small; and the insulation properties deteriorate.

The present invention has been made in view of the above-mentioned circumstances, and an object of the present invention is to provide an EBG structure which has a band gap in a specific frequency range and which can be downsized and thinned, a filter element, an antenna element, a substrate with a built-in element, a semiconductor device, and a multi-chip module using the EBG structure, and production methods thereof.

### Solution to Problem

An electromagnetic band gap structure according to an exemplary aspect of the present invention includes: an insulating substrate; a plurality of conductor pieces regularly arranged on the insulating substrate; a dielectric layer formed so as to fill a space between adjacent ones of the conductor pieces; an interlayer insulating layer formed on the dielectric layer; and a conductor plane that is formed on the interlayer insulating layer and is connected to each of the conductor pieces with a conductor penetrating through the interlayer insulating layer.

A production method of an electromagnetic band gap structure according to another exemplary aspect of the present invention includes: forming a plurality of conductor pieces regularly on an insulating substrate; forming a dielectric layer so as to fill a space between adjacent ones of the conductor pieces; forming an interlayer insulating layer on the dielectric layer; and forming a conductor plane on the interlayer insulating layer, the conductor plane being connected to each of the conductor pieces.

### Advantageous Effects of Invention

According to the present invention, it is possible to provide an EBG structure which has a band gap in a specific frequency range and which can be downsized and thinned, a filter element, an antenna element, a substrate with a built-in element, a semiconductor device, and a multi-chip module using the EBG structure, and production methods thereof.

### BRIEF DESCRIPTION OF DRAWINGS

FIG. 1 is a perspective view showing an EBG structure according to a first exemplary embodiment;

FIG. 2 is a cross-sectional view showing the EBG structure according to the first exemplary embodiment;

FIG. 3A is a production process cross-sectional view illustrating a production method of the EBG structure according to the first exemplary embodiment;

FIG. 3B is a production process cross-sectional view illustrating the production method of the EBG structure according to the first exemplary embodiment;

FIG. 3C is a production process cross-sectional view illustrating the production method of the EBG structure according to the first exemplary embodiment;

FIG. 3D is a production process cross-sectional view illustrating the production method of the EBG structure according to the first exemplary embodiment;

FIG. 3E is a production process cross-sectional view illustrating the production method of the EBG structure according to the first exemplary embodiment;

FIG. 3F is a production process cross-sectional view illustrating the production method of the EBG structure according to the first exemplary embodiment;

FIG. 3G is a production process cross-sectional view illustrating the production method of the EBG structure according to the first exemplary embodiment;

FIG. 4 is a cross-sectional view showing another example of the EBG structure according to the first exemplary embodiment;

FIG. 5 is a cross-sectional view showing an EBG structure according to a second exemplary embodiment;

FIG. 6A is a production process cross-sectional view illustrating a production method of the EBG structure according to the second exemplary embodiment;

FIG. 6B is a production process cross-sectional view illustrating the production method of the EBG structure according to the second exemplary embodiment;

FIG. 6C is a production process cross-sectional view illustrating the production method of the EBG structure according to the second exemplary embodiment;

FIG. 6D is a production process cross-sectional view illustrating the production method of the EBG structure according to the second exemplary embodiment;

FIG. 6E is a production process cross-sectional view illustrating the production method of the EBG structure according to the second exemplary embodiment;

FIG. 6F is a production process cross-sectional view illustrating the production method of the EBG structure according to the second exemplary embodiment;

FIG. 7 is a cross-sectional view showing an EBG structure according to a third exemplary embodiment;

FIG. 8A is a production process cross-sectional view illustrating the production method of the EBG structure according to the third exemplary embodiment;

FIG. 8B is a production process cross-sectional view illustrating the production method of the EBG structure according to the third exemplary embodiment;

FIG. 8C is a production process cross-sectional view illustrating the production method of the EBG structure according to the third exemplary embodiment;

FIG. 8D is a production process cross-sectional view illustrating the production method of the EBG structure according to the third exemplary embodiment;

FIG. 8E is a production process cross-sectional view illustrating the production method of the EBG structure according to the third exemplary embodiment;

FIG. 8F is a production process cross-sectional view illustrating the production method of the EBG structure according to the third exemplary embodiment;

FIG. 8G is a production process cross-sectional view illustrating the production method of the EBG structure according to the third exemplary embodiment;

FIG. 8H is a production process cross-sectional view illustrating the production method of the EBG structure according to the third exemplary embodiment;

FIG. 9 is a perspective view showing an example of the EBG structure in which an inductance element is explicitly added;

FIG. 10 is a cross-sectional view showing a structure of a filter component to which the present invention is applied;

FIG. 11 is a schematic view showing a structure of a substrate with a built-in element which has built therein the filter component to which the present invention is applied;

FIG. 12A is a production process cross-sectional view illustrating a production method of the substrate with a built-in element which has built therein the filter component to which the present invention is applied;

FIG. 12B is a production process cross-sectional view illustrating the production method of the substrate with a built-in element which has built therein the filter component to which the present invention is applied;

FIG. 12C is a production process cross-sectional view illustrating the production method of the substrate with a built-in element which has built therein the filter component to which the present invention is applied;

FIG. 12D is a production process cross-sectional view illustrating the production method of the substrate with a built-in element which has built therein the filter component to which the present invention is applied;

FIG. 12E is a production process cross-sectional view illustrating the production method of the substrate with a built-in element which has built therein the filter component to which the present invention is applied;

FIG. 12F is a production process cross-sectional view illustrating the production method of the substrate with a built-in element which has built therein the filter component to which the present invention is applied;

FIG. 12G is a production process cross-sectional view illustrating the production method of the substrate with a built-in element which has built therein the filter component to which the present invention is applied;

FIG. 12H is a production process cross-sectional view illustrating the production method of the substrate with a built-in element which has built therein the filter component to which the present invention is applied;

FIG. 13 is a cross-sectional view showing a structure of a multi-chip module in which the filter component to which the present invention is applied is fabricated;

FIG. 14 is a cross-sectional view showing a structure of a thin-film filter component to be built in a substrate to which the present invention is applied;

FIG. 15A is a production process cross-sectional view illustrating a production method of the thin-film filter component to be built in the substrate to which the present invention is applied;

FIG. 15B is a production process cross-sectional view illustrating the production method of the thin-film filter component to be built in the substrate to which the present invention is applied;

FIG. 15C is a production process cross-sectional view illustrating the production 25, method of the thin-film filter component to be built in the substrate to which the present invention is applied;

FIG. 15D is a production process cross-sectional view illustrating the production method of the thin-film filter component to be built in the substrate to which the present invention is applied;

FIG. 15E is a production process cross-sectional view illustrating the production method of the thin-film filter component to be built in the substrate to which the present invention is applied;

FIG. 15F is a production process cross-sectional view illustrating the production method of the thin-film filter component to be built in the substrate to which the present invention is applied;

FIG. 15G is a production process cross-sectional view illustrating the production method of the thin-film filter component to be built in the substrate to which the present invention is applied; and

FIG. 15H is a production process cross-sectional view illustrating the production method of the thin-film filter component to be built in the substrate to which the present invention is applied.

### DESCRIPTION OF EMBODIMENTS

### First Exemplary Embodiment

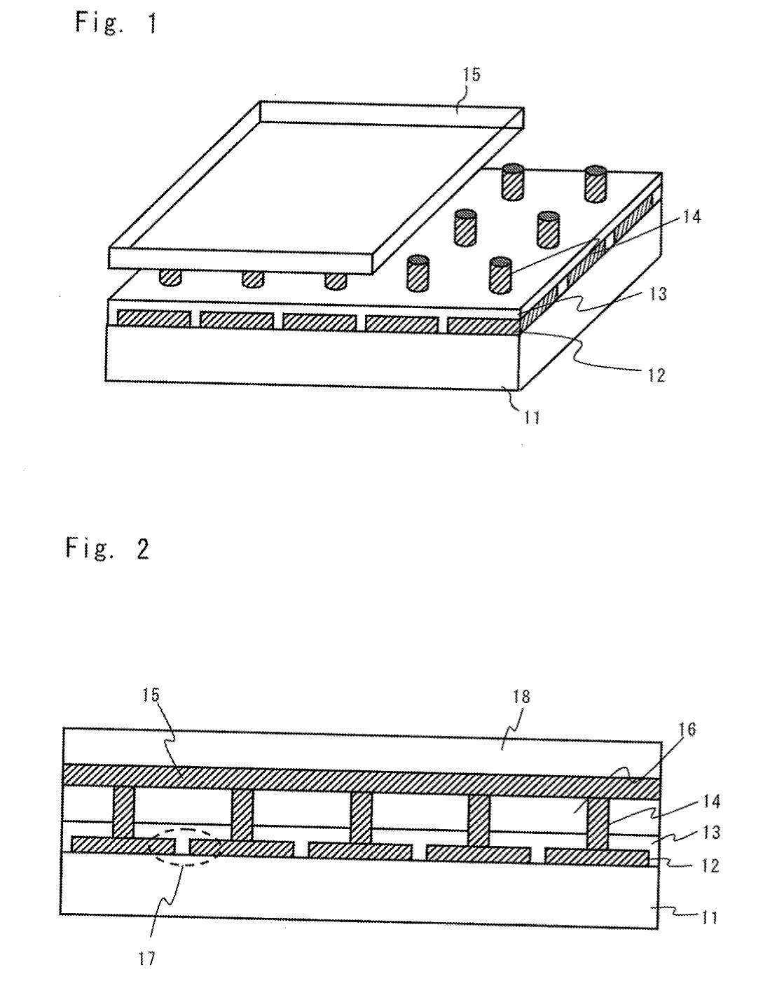

An electromagnetic band gap structure (EBG structure) according to a first exemplary embodiment of the present invention will be described with reference to the drawings. FIG. 1 is a perspective view showing the EBG structure according to this exemplary embodiment, and FIG. 2 is a cross-sectional view thereof. In FIG. 1, a part of a conductor plane 15 and an interlayer insulating film 16 are omitted to facilitate illustration of the internal structure.

As shown in FIGS. 1 and 2, the electromagnetic band gap structure according to this exemplary embodiment includes an insulating substrate 11, conductor pieces 12, a dielectric layer 13, connection conductors 14, the conductor plane 15, the interlayer insulating film 16, and a cover film 18. The conductor pieces 12, which are regularly arranged two-dimensionally, are formed on the insulating substrate 11 which is flat and resistant to heat.

Each of the conductor pieces 12 preferably has a stacked structure of an intermediate layer which is formed of at least one layer selected from the group consisting of Ti, Ta, Cr, and nitrides of these elements and which is formed from the side of the insulating substrate 11, and at least one layer which is selected from the group consisting of Pt, Pd, Ru, and Ir and which is formed on the upper layer side of the intermediate layer. The reason is that since a high-temperature oxidizing atmosphere is necessary to form the dielectric layer 13, which is described later, it is desirable to use a refractory conductor layer having a high melting point and oxidation resistance, such as Pt, as a metal layer formed below the dielectric layer 13, in particular, as a layer in contact with the dielectric layer 13. Meanwhile, refractory metals are stable but have poor reactivity, and thus may exhibit an insufficient adhesion to a layer formed below. The use of a material excellent in reactivity, such as Ti, as the intermediate layer can improve the adhesion to the insulating substrate 11 which is formed below the intermediate layer.

The dielectric layer 13 is formed on the plurality of conductor pieces 12 so as to cover the conductor pieces 12 and fill a space between adjacent ones of the conductor pieces 12. The dielectric layer 13 is preferably formed of a metal oxide having a relative permittivity of 10 or more, and more preferably 100 or more. The use of a high-dielectric-constant material as the dielectric layer 13 can increase the capacitance and can exhibit a band gap in a desired frequency range with a smaller area. Alternatively, it is possible to exhibit a band gap in a lower frequency range with the same area. For instance, it is preferable to use a high-dielectric-constant material as the dielectric layer 13, because a capacitance of approximately one nF is required to exhibit a band gap in a frequency band of several GHz, like a wireless LAN. Moreover, when the dielectric layer 13 is formed of a metal oxide, the conductor plane 15 formed above the dielectric layer 13 is preferably formed of a refractory noble metal or a refractory conductive oxide.

The interlayer insulating film 16 is formed on the dielectric layer 13. The dielectric layer 13 has a relative permittivity greater than that of the other interlayer insulating film 16. Additionally, the conductor plane 15 is formed on the interlayer insulating film 16.

The dielectric layer 13 and the interlayer insulating film 16 have vias formed therein that allow the conductive pieces 12 formed in the lower layer to be partially exposed. The connection conductors 14 are formed in the respective vias. The conductor pieces 12 are connected to the conductor plane 15 through the respective connection conductors 14.

A capacitance element 17 is formed between adjacent ones of the conductor pieces 12. One of the conductor pieces 12, one of the connection conductors 14, and a part of the conductor plane 15 constitute an inductance element. The frequency band in which a band gap is generated can be controlled by the capacitance element and the inductance element.

According to the present invention, the dielectric layer 13 can be thinned and increased in dielectric constant, thereby making it possible to increase the capacitance between the conductor plane and the conductor pieces and to exhibit a band gap in a lower frequency range. This facilitates controlling and designing the bandwidth of the band gap.

Further, the whole structure can be thinned by a thin film process, and the capacitance per unit area can be increased. Accordingly, even when the same capacity is required, the conductor pieces can be downsized. Consequently, downsizing and thinning of the entire EBG structure can be achieved, which contributes to downsizing and thinning of the device to be mourned.

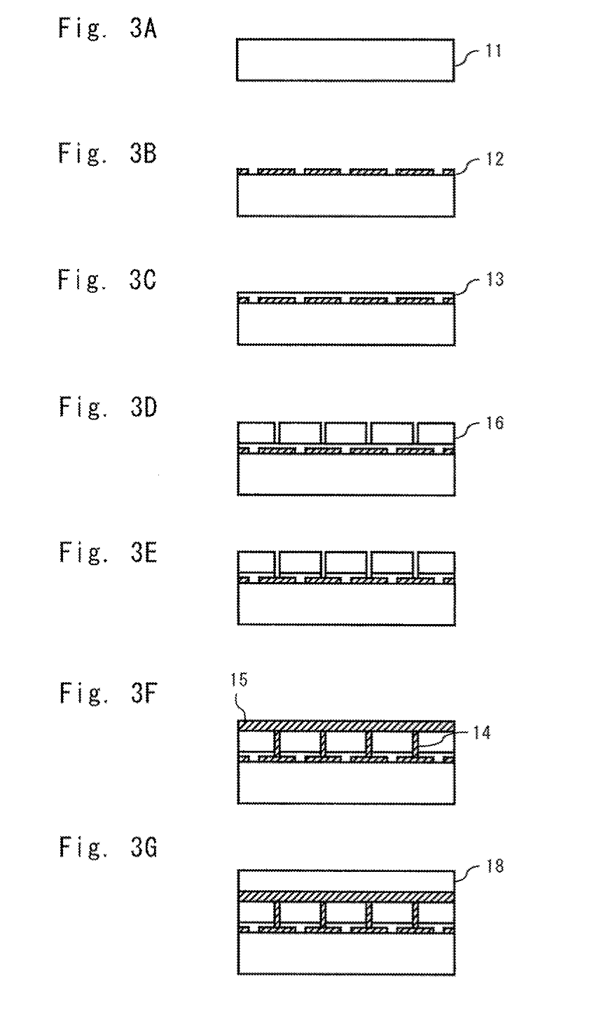

Referring now to FIGS. 3A to 3G, a production method of the electromagnetic band gap structure according to this exemplary embodiment is described. FIGS. 3A to 3G are production process cross-sectional views each illustrating the production method of the electromagnetic band gap structure according to this exemplary embodiment. As shown in FIG. 3A, a borosilicate glass substrate, for example, is prepared as the insulating substrate 11.

Then, stacked films of Ti (50 nm) and Pt (200 nm) are deposited in this order on the insulating substrate 11 by sputtering. After that, a resist is formed in the shape of the conductor pieces 12, and the other portions are etched and removed by ion milling (FIG. 3B). Note that the interval between the conductor pieces is designed to be larger than the thickness.

After the resist is removed, strontium titanate is deposited on the entire surface with a thickness of 500 nm as the dielectric layer 13, at a deposition temperature of 450° C. in a sputtering atmosphere of 80% Ar and 20% O₂, by using an RF sputtering method (FIG. 3C). According to experiments conducted by the inventors, a strontium titanate thin film having a relative permittivity of 200 can be obtained under such conditions. If the strontium titanate film is deposited with a thickness greater than that of the Pt/Ti stacked films serving as the conductor pieces 12 and the interval between the conductor pieces 12 is designed to be larger than the thickness, the strontium titanate film can fill the space between the conductor pieces 12 without any difficulty.

After that, a photosensitive polyimide resin is applied onto the dielectric layer B as the interlayer insulating film 16 with a thickness of 15 Then, vias for forming the connection conductors 14 are opened in the interlayer insulating film 16 by lithography (FIG. 3D). Subsequently, the dielectric layer 13 made of strontium titanate is etched using the interlayer insulating film 16 having the vias formed therein as a mask and using a mixture of hydrofluoric acid, nitric acid, and pure water, thereby partially exposing the conductor pieces 12 (FIG. 3E).

Next, Cu (300 nm)/Ti (50 nm) stacked films serving as a seed layer are deposited on the entire surface by sputtering. After that, Cu is deposited by electrolytic plating with a thickness of 15 μm at a flat end of the surface, thereby forming the conductor plane 15. At the same time, the vias formed in the interlayer insulating film 16 and the dielectric layer 13 are filled up by Cu plating, thereby forming the connection conductors 14 for connecting the conductor pieces 12 with the conductor plane 15 (FIG. 3F). Lastly, the cover layer 18 is formed using a resin with external connection pads left (FIG. 3G).

In this exemplary embodiment, as long as the conductor pieces 12 are formed using a heat-resistant metal, a metal oxide having a high relative permittivity can be directly filled in the space between the conductor pieces 12 each functioning as a capacitance element. This makes it possible to increase the capacitance and to reduce the area of the conductor pieces 12.

Meanwhile, in the processes after the formation of the dielectric layer 13 which is formed of a metal oxide, materials having a high heat resistance are not required. For this reason, a circuit can be formed using a low-cost resin, a thick plated line with low resistance, and the like. Furthermore, the conductor pieces 12 for forming the capacitance element are first formed on the flat insulating substrate 11. This is advantageous in that high-precision lithography and etching processes can be accomplished and the bandwidth of the EBG can be easily controlled with little difference from the design.

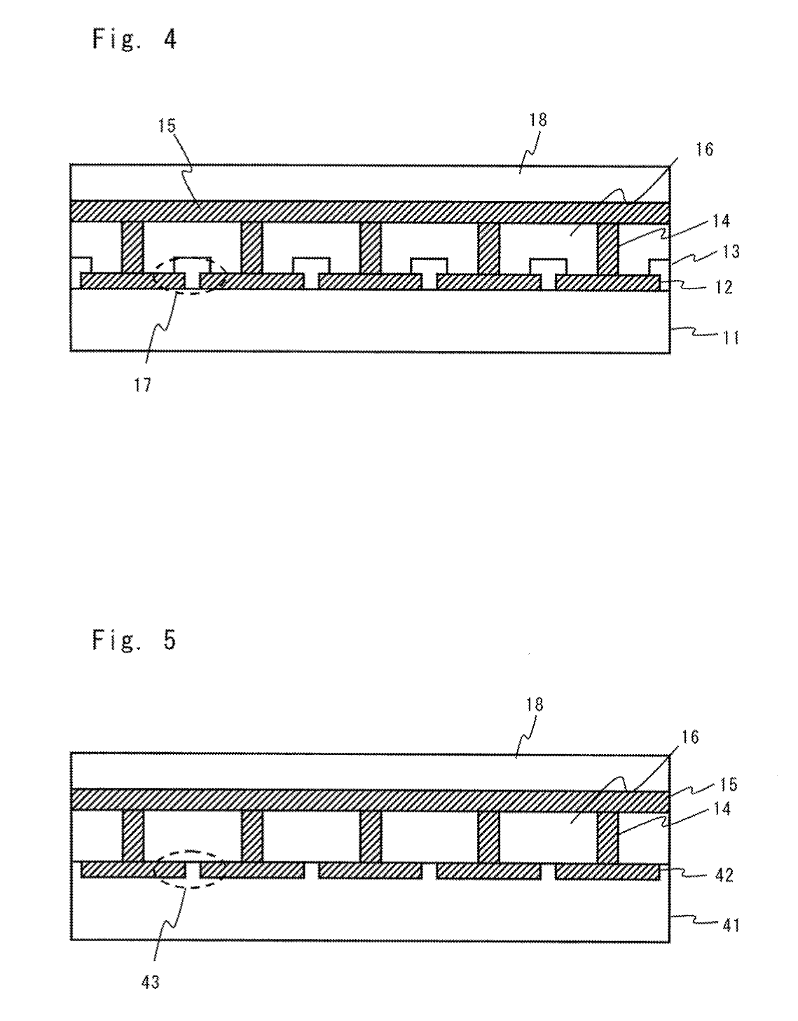

FIG. 4 shows another example of the EBG structure according to this exemplary embodiment. As shown in FIG. 4, the dielectric layer 13 may be formed between the conductor pieces 12 and in the vicinity thereof. In the example shown in FIG. 4, the area in which the dielectric layer 13 and the interlayer insulating film 16 formed in the upper layer are in contact with each other can be reduced. If the adhesion between these films is low, it is advantageous in terms of improvement in reliability.

The dielectric layer 13 can be formed by removing unnecessary portions by photolithography and etching after the material of the dielectric layer 13 is deposited. Alternatively, the dielectric layer 13 can also be formed by depositing the dielectric layer 13 in the state where a metal mask is brought into contact with the unnecessary portions so as to cover them. In this case, the processes in which photolithography is not required are simplified.

### Second Exemplary Embodiment

An EBG structure according to a second exemplary embodiment of the present invention will be described with reference to the drawings. FIG. 5 is a cross-sectional view showing the EBG structure according to this exemplary embodiment. As shown in FIG. 5, the EBG structure according to this exemplary embodiment includes a dielectric insulating substrate 41, conductor pieces 42, the connection conductors 14, the conductor plane 15, the interlayer insulating film 16, and the cover film 18. In a method of filling a dielectric layer in a space between the conductor pieces, the dielectric layer is filled after the formation of the conductor pieces in the first exemplary embodiment. Alternatively, in this exemplary embodiment, it can be achieved by burying the conductor pieces in the dielectric layer.

As shown in FIG. 5, the conductor pieces 42, which are regularly arranged two-dimensionally, are buried in an upper portion of the dielectric insulating substrate 41. The interlayer insulating film 16 is formed on the conductor pieces 42. Vias for partially exposing the conductor pieces 42 are formed at predetermined positions of the interlayer insulating film 16. The connection conductors 14 are formed in the respective vias of the interlayer insulating film 16.

The conductor plane 15 is formed on the interlayer insulating film 16. The conductor plane 15 is connected to the conductor pieces 42 in the lower layer through the connection conductors 14. The cover film 18 is formed on the conductor plane 15. A capacitance element 43 is formed between adjacent ones of the conductor pieces 42.

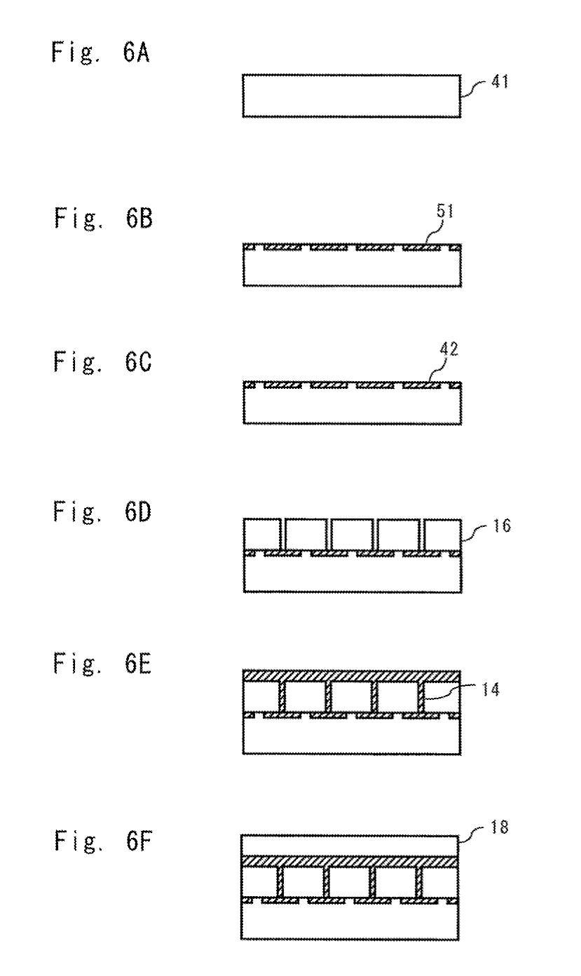

Referring now to FIGS. 6A to 6F, a production method of the EBG structure according to this exemplary embodiment is described. FIGS. 6A to 6F are production process cross-sectional views each illustrating the production method of the EBG structure according to this exemplary embodiment. As shown in FIG. 6A, a lead zirconate titanate ceramic plate is first prepared as the dielectric insulating substrate 41.

Further, a resist pattern having openings corresponding to the shapes of the conductor pieces 42 is formed on the dielectric insulating substrate 41. Cavities are formed at the openings by a micro-blast method with the resist as a mask. Furthermore, Cu (300 nm)/Ti (50 nm) stacked films serving as a seed layer are deposited on the entire surface by sputtering. After that, Cu is deposited with a thickness greater than the depth of the cavities by electrolytic plating, thereby filling the cavities (FIG. 6B). Then, the surface is subjected to chemical mechanical polishing (CMP) to form a structure in which the conductor pieces 42 are buried in the dielectric insulating substrate 41 (FIG. 6C).

A photosensitive polyimide resin is applied onto the dielectric insulating substrate 41, in which the conductor pieces 42 are buried, as the interlayer insulating film 16 with a thickness of 10 μm. Then, vias for contacting the conductor pieces 42 are formed in the interlayer insulating film 16 by lithography (FIG. 6D). After that, the connection conductors 14, which are obtained by filling the vias, and the conductor plane 15, which is formed in the upper layer, are formed such that Cu (300 nm)/Ti (50 nm) stacked films serving as a seed layer are deposited on the entire surface by sputtering and Cu is then deposited with a thickness of 15 μm at a flat portion of the surface by electrolytic plating (FIG. 6E). Lastly, the cover layer is formed using a resin with external connection pads left (FIG. 6F).

In this exemplary embodiment, the use of a bulk of high-dielectric-constant material enables sufficient burning at a higher temperature than the thin dielectric layer 13. This makes it possible to fill a dielectric material having a high relative permittivity and excellent insulating properties in the space between the conductor pieces 42. For example, lead zirconate titanate ceramic has a relative permittivity of 1000 or more and can increase the capacitance several hundred times as large as that of a resin.

### Third Exemplary Embodiment

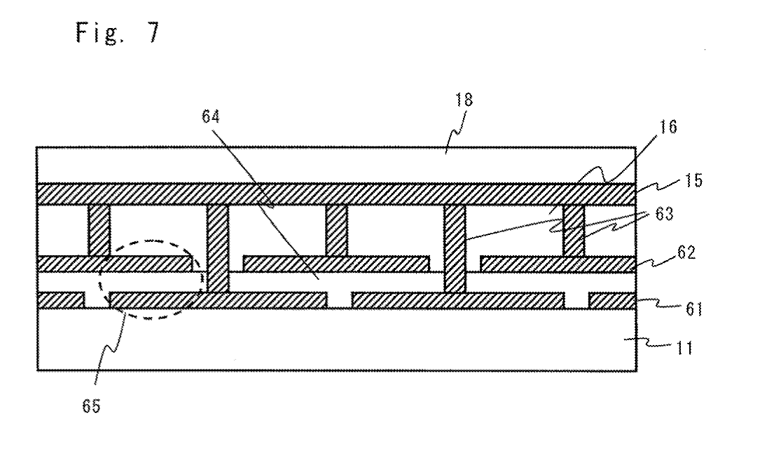

An EBG structure according to a third exemplary embodiment of the present invention will be described with reference to FIG. 7. FIG. 7 is a cross-sectional view showing the EBG structure according to this exemplary embodiment. As shown in FIG. 7, in this exemplary embodiment, conductor pieces are arranged in two layers, and a capacitance element is formed between the conductor pieces which overlap each other in the vertical direction.

As shown in FIG. 7, the EBG structure according to this exemplary embodiment includes the insulating substrate 11, first conductor pieces 61, second conductor pieces 62, connection conductors 63, a dielectric layer 64, the conductor plane 15, the interlayer insulating film 16, and the cover film 18. The conductor pieces 61, which are regularly arranged two-dimensionally, are formed on the insulating substrate 11. The dielectric layer 64 is formed on the first conductor pieces 61.

The second conductor pieces 62, which are regularly arranged two-dimensionally, are formed on the dielectric layer 64. The second conductor pieces 62 are arranged so as to partially overlap the first conductor pieces 61 through the dielectric layer 64.

Each of the first and second conductor pieces 61 and 62 preferably has a stacked structure of an intermediate layer which is formed of at least one layer selected from the group consisting of Ti, Ta, Cr, and nitrides of these elements and which is formed from the side of the insulating substrate 11, and at least one layer which is selected from the group consisting of Pt, Pd, Ru, and Ir and which is formed on the upper layer side of the intermediate layer.

The interlayer insulating film 16 is formed on the second conductor pieces 62. The dielectric layer 64 has a relative permittivity greater than that of the other interlayer insulating film 16. The interlayer insulating film 16 and the dielectric layer 64 have vias formed therein that allow the first conductor pieces 61 to be partially exposed. The interlayer insulating film 16 has vias formed therein that allow the second conductor pieces 62 to be partially exposed. The vias for exposing the first conductor pieces 61 are formed between the second conductor pieces 62. The connection conductors 63 are respectively formed within the vias. The conductor plane 15 is formed on the interlayer insulating film 16.

The plurality of first conductor pieces 61 are connected to the conductor plane 15 through the respective connection conductors 63 within vias that are formed in the interlayer insulating film 16 and the dielectric layer 64. The plurality of second conductor pieces 62 are also connected to the conductor plane 15 through the respective connection conductors 63 within the vias formed in the interlayer insulating film 16. The cover film 18 is formed on the conductor plane 15.

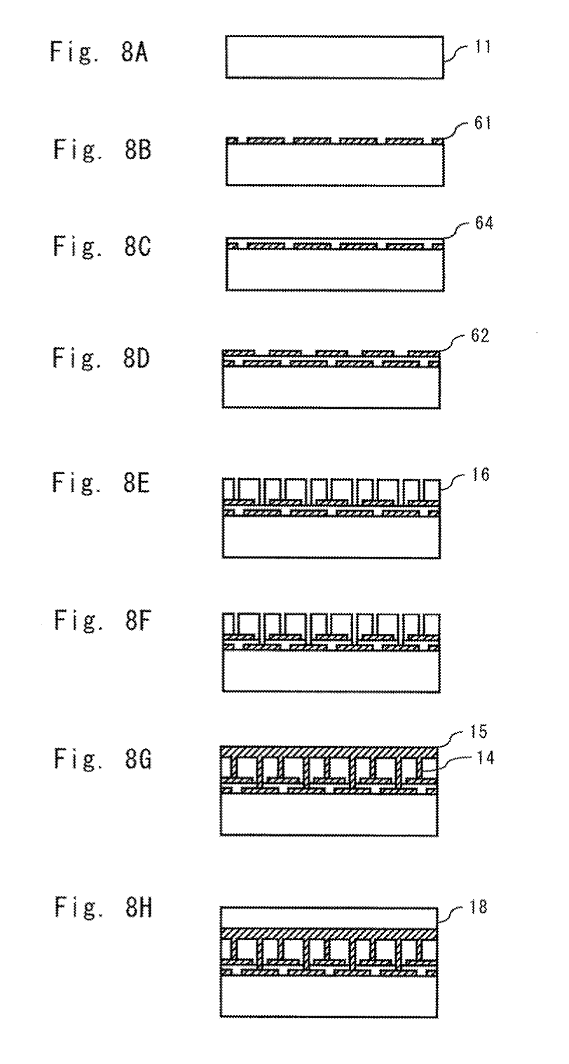

Referring now to FIGS. 8A to 8H, a production method of the EBG structure according to this exemplary embodiment is described. FIGS. 8A to 8H are production process cross-sectional views each illustrating the production method of the EBG structure according to this exemplary embodiment. As shown in FIG. 8A, a borosilicate glass substrate is prepared as the insulating substrate 11. Stacked films of Ti (50 nm) as an intermediate layer and Pt (200 nm) as a high-melting-point conductor layer formed in the upper layer are deposited on the insulating substrate 11 in this order by sputtering. After that, a resist is formed in the shape of the first conductor pieces 61, and the other portions are etched and removed by ion milling, thereby forming the first conductor pieces 61 (FIG. 8B). Then, after the resist is removed, barium titanate/strontium is deposited on the entire surface with a thickness of 100 nm as the dielectric layer 64, at a deposition temperature of 600° C. in a sputtering atmosphere of 80% Ar and 20% O₂, by an RF sputtering method (FIG. 8C).

Further, TiN (50 nm) as an intermediate layer and Pt (200 nm) as a refractory conductor layer are stacked on the dielectric layer 64 by a sputtering method, and the second conductor pieces 62 are formed by lithography and wet etching (FIG. 8D). Then, a photosensitive polyimide resin is applied onto the second conductor pieces 62 as the interlayer insulating film 16 with a thickness of 15 μM. After that, vias for forming the connection conductors 14 are opened in the interlayer insulating film 16 by lithography (FIG. 8E). The vias are formed in the interlayer insulating film 16 at positions corresponding to the first conductor pieces 61 and the second conductor pieces 62, thereby partially exposing the second conductor pieces 62.

Subsequently, barium titanate/strontium serving as the dielectric layer 64 is etched using the interlayer insulating film 16 having the vias formed therein as a mask and using a mixture of hydrofluoric acid, nitric acid, and pure water, thereby also partially exposing the conductor pieces 61 (FIG. 8F).

Next, Cu (300 nm)/Ti (50 nm) stacked films serving as a seed layer are deposited on the entire surface by sputtering, and Cu is then deposited by electrolytic plating with a thickness of 15 μm at a flat portion of the surface, thereby forming the conductor plane 15 (FIG. 8G). At the same time, the vias formed in the interlayer insulating film 16 and the dielectric layer 64 are filled up by Cu plating, thereby forming the connection conductors 14 for connecting the first conductor pieces 61 with the conductor plane 15 and the second conductor pieces 62 with the conductor plane 15, respectively. Lastly, the cover film 18 is formed using a resin with external connection pads left (FIG. 8H).

In this exemplary embodiment, the first conductor pieces 61 and the second conductor pieces 62 each function as a capacitance element 65. Thus, as compared with the first and second exemplary embodiments, the electrode area of the capacitance element can be increased, which is advantageous in increasing the capacitance.

Further, in this exemplary embodiment, there is no need to completely fill the space between the first conductor pieces 61 with the dielectric layer 64. This permits reduction in the thickness of the dielectric layer 64. The interval between the first conductor pieces 61 and the second conductor piece 62 is preferably 1 μm or less. The capacitance can be further increased by reducing the interval between the first conductor pieces 61 and the second conductor piece 62. Consequently, the area of each of the first conductor pieces 61 and the second conductor piece 62 can be further downsized.

Even when conductor pieces disposed in different layers form a primary capacitance element as in this exemplary embodiment, a high-dielectric-constant material can be deposited on the conductor pieces with a thickness of 1 μm or less. For this reason, the interval between the conductor pieces can be reduced by one order of magnitude or more and the capacitance can be increased as compared with the sheet stacking method of the related art. For example, when a strontium titanate film with a relative permittivity of 120 and a thickness of 1 μm is used as a dielectric layer, a capacitance of about 1 nF per 1 mm² which is about 1000 times as large as that of a printed wiring board material can be obtained.

Note that, in this exemplary embodiment, the first conductor pieces 61 and the second conductor pieces 62 which are formed in two layers are used, but may be formed in three or more layers. In this case, the process for stacking the conductor pieces, the metal oxide, and the conductor pieces may be repeated so that the conductor pieces are formed in three or more layers.

In the above-mentioned exemplary embodiments, as high-dielectric-constant materials for forming the dielectric layer 13, the dielectric insulating substrate 41, and the dielectric layer 64, a perovskite oxide represented by a chemical formula of AB₃ (A and B are metal elements), such as lead zirconate titanate, strontium titanate, and barium titanate, a pyrochlore oxide represented by a chemical formula of A₂B₂O₇ (A and B are metal elements), a Bi-layered ferroelectric such as SrBi₂Ta₂O₉, and a composite oxide containing these elements as a component may be used. By the use of these materials, a high dielectric constant of several hundreds to 1000 or more is obtained in bulk ceramics, and a high dielectric constant of several tens to several hundreds is obtained in a thin film state.

As the high-dielectric-constant materials, oxides of Mg, Al, Ti, Ta, Hf, and Zr may also be used. These materials have a relative permittivity greater than that of resin and are advantageous in increasing the capacitance and the capacitance per unit area. It is desirable that these oxides be formed at a high temperature and in an oxygen atmosphere so as to obtain an excellent insulating property.

Note that these oxides may be formed not only by the sputtering method but also by a CVD method, a sol-gel method, and an aerosol deposition method. A high-quality insulating film can be obtained also by these methods through the deposition process and heat treatment at a temperature of 300° C. or higher and in the oxygen atmosphere.

Thus, in order to achieve formation of thin films of the dielectric layer 13 and the dielectric layer 64 at a high temperature and in an oxygen atmosphere, an appropriate conductor layer having a high-melting-point is required. In this exemplary embodiment, Pt is used as the high-melting-point conductor layer. This is because Pt is stable in the temperature range of 300 to 600° C., which is necessary for the formation of the dielectric layer 13 and the like, and does not form any oxide layer having a low dielectric constant even in the oxygen atmosphere. For the same reasons, not only Pd but also Ru and Ir may be used.

Note that Pd, Ru, and Ir may form oxides in the oxygen atmosphere. However, these oxides are conductors that do not reduce the effective capacitance of the capacitance element. As the refractory conductive layer, conductive oxides such as RuO₂ and IrO₂ may also be used in advance. As the substrate, not only glass but stable insulating materials such as sapphire, quartz, and alumina can be used.

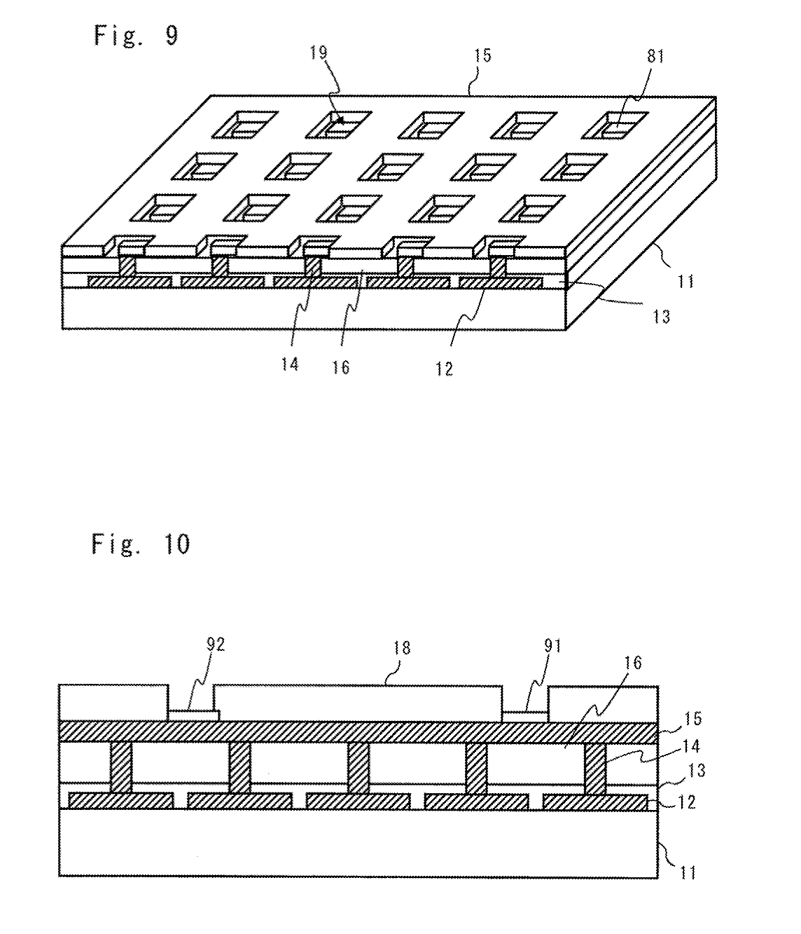

In the above-mentioned exemplary embodiments, means for increasing the capacitance as well as the inductance may also be used to control the band gap frequency range. FIG. 9 is a perspective view showing an example of an EBG structure in which an inductance element is explicitly added. Here, the EGB structure according to the first exemplary embodiment is shown in which an inductance element is explicitly added to the conductor plane 15.

As shown in FIG. 9, openings 19 are formed in the vicinity of the connection conductors 14 of the conductor plane 15. Inductance elements 81 which are linear inductors are formed in the respective openings 19. The inductance elements 81 are connected to the conductor plane 15 and the respective connection conductors 14. That is, the conductor pieces 12, the connection conductors 14, the inductance elements 81, and the conductor plane 15 are connected to one another. To obtain a desired inductance, the same effects can be obtained not only in the linear inductor but also in a spiral inductor.

The inductance elements 81 cause a surface roughness which makes it difficult to form a dielectric layer that has a thickness smaller than that of a wiring layer and exhibits an excellent insulation property, as an upper layer. However, in the present invention, the inductance elements 81 are formed after the formation of the dielectric layer 13, causing no effect on the formation of the dielectric layer 13.

As described above, the use of the present invention enables significant downsizing of the EGB structure formed in an area of several cm□ on a related art printed wiring board. Typically, the downsizing can be achieved in the size of 1 cm□ (1 cm×1 cm) or less.

This facilitates mounting of an electric device at a desired position as a discrete component. For example, the EBG structure according to the present invention can be used as a reflector of a patch antenna as described in Patent Literatures 1 to 4. An antenna element is provided with an EBG structure and a feeder connected to a part of the conductor plane of the EBG structure. Designing the antenna element so that the use frequency range of the antenna falls within the band gap of the EBG structure prevents propagation of a surface wave within the EBG structure. This makes it possible to suppress reflection at the back surface and prevent deterioration in antenna characteristics.

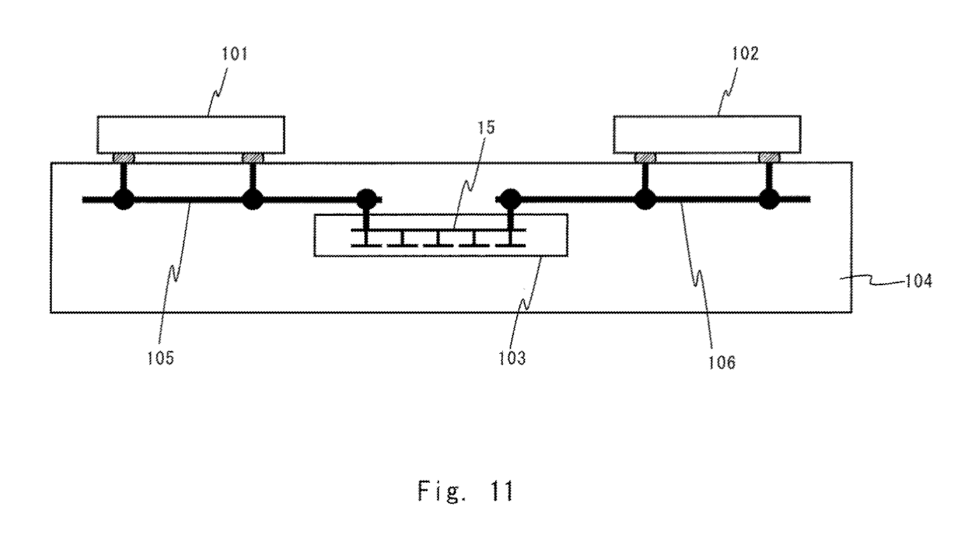

It is also possible to form a filter component by using the EBG structure according to the present invention. Hereinafter, a structure of a filter component using the EBG structure according to the present invention is described with reference to FIG. 10. FIG. 10 is a cross-sectional view showing a structure of a common mode filter which is formed as a chip component according to this exemplary embodiment. FIG. 10 shows only a part of the common mode filter including external connection terminals.

As shown in FIG. 10, the common mode filter according to this exemplary embodiment includes the insulating substrate 11, the conductor pieces 12, the dielectric layer 13, the connection conductors 14, the conductor plane 15, the interlayer insulating film 16, the cover film 18, and external connection terminals 91 and 92. In this exemplary embodiment, as in the first exemplary embodiment, the conductor pieces 12 are regularly arranged two-dimensionally on the insulating substrate 11. Further, the dielectric layer 13, the conductor plane 15, the interlayer insulating film 16, and the cover film 18 are stacked in this order on the conductor pieces 12. The conductor plane 15 and the conductor pieces 12 are connected to each other with the connection conductors 14 which are respectively formed within the vias that are formed in the dielectric layer 13 and the interlayer insulating film 16.

The cover film 18 is opened so as to expose a part of the conductor plane 15. The exposed portions of the conductor plane 15 serve as the external connection terminals 91 and 92. The external connection terminals 91 and 92 are preferably subjected so surface treatment, such as Au plating, depending on the connection method. As a result, the connection reliability can be improved. Furthermore, the cover film 18 protects the conductor plane 15, and at the same time prevents the outflow of solder during solder bonding. Thus, the common mode filter having such an EBG structure is formed as a small chip component, thereby enabling surface mounting.

Additionally, the common mode filter can be mounted not only on the surface but also inside the printed wiring board. FIG. 11 is a schematic diagram showing a structure of a substrate with a built-in element in which the filter component to which the present invention is applied is incorporated. The substrate with a built-in element shown in FIG. 11 includes a device 101 which is a noise generation source, a device 102 which is susceptible to noise, a common mode filter component 103, a printed wiring board 104, a first ground plane 105, and a second ground plane 106. Assume herein that the common mode filter component 103 has the EBG structure described in the first exemplary embodiment.

The common mode filter component 103 is buried in the printed wiring board 104. The printed wiring board 104 is provided with the first ground plane 105 and the second ground plane 106. The first ground plane 105 and the second ground plane 106 are separated from each other. The conductor plane 15 of the common mode filter component 103 is connected to each of the first ground plane 105 and the second ground plane 106 which are different planes separated from each other.

The device 101, which is a noise generation source, and the device 102, which is susceptible to noise, are mounted on the printed wiring board 104. The device 101, which is a noise generation source, is connected to the first ground plane 105, and the device 102, which is susceptible to noise, is connected to the second ground plane 106.

The process for incorporating the common mode filter component 103 as described above can be carried out in the same manner as in the process for incorporating an LSI or a chip component. When the common mode filter component 103 is not mounted on the surface but built in the substrate, another device can be mounted on the surface. Furthermore, the present invention enables downsizing as compared to the case where the device is formed by wiring of a printed wiring board.

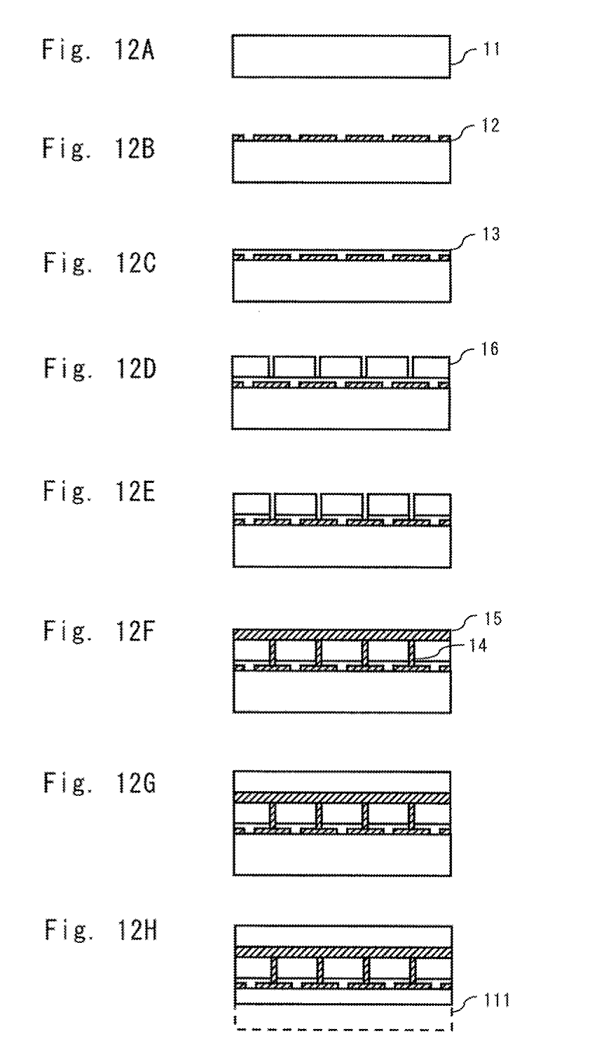

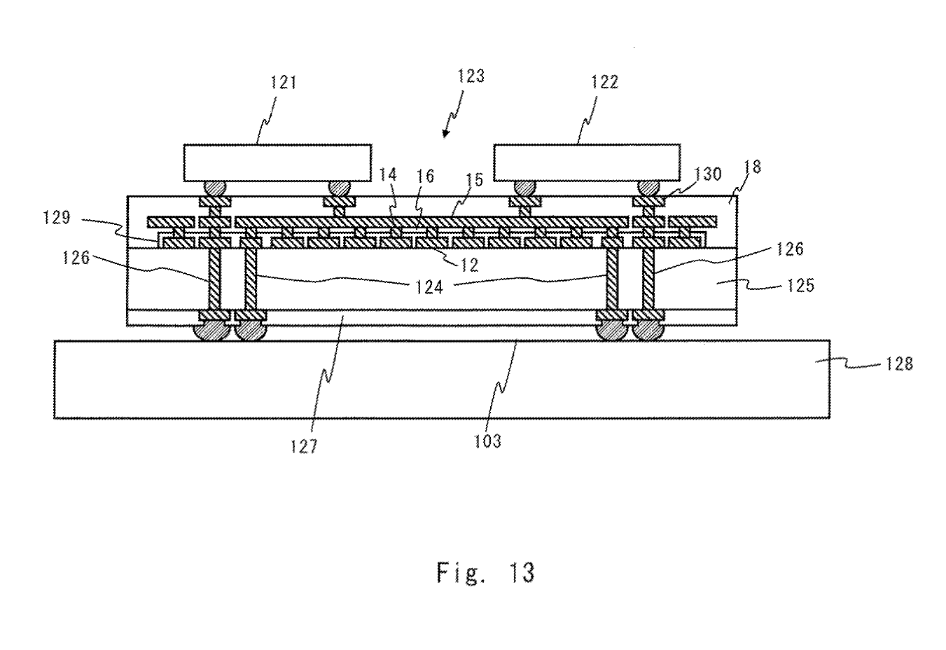

FIGS. 12A to 12H are production process cross-sectional views each illustrating a production method of the substrate with a built-in element in which the filter component to which the present invention is applied is incorporated. FIGS. 12A to 12G illustrate that the EBG structure is formed on the insulating substrate 11, as in FIGS. 2A to 2G. The EBG structure corresponds to a portion built up on the insulating substrate 11 which is a rigid substrate. After that, the insulating substrate 11 is ground or etched from the back side to remove a removal portion 111, thereby reducing the thickness (FIG. 12H).

When the entire thickness of the EBG structure is set to 300 μm or less, the structure can be embedded into printed circuit boards like small chip components. Thus, the filter component can be embedded the printed wiring board 104 without any additional special process. The thickness of the insulating substrate 11 may be further reduced depending on the embedding process.

FIG. 13 is a schematic view showing a multi-chip module and system-in-package in which the EBG structure is incorporated by using the insulating substrate, which is flat and has a heat resistance, as an interposer. Note that, in FIG. 13, lines between chips, power supply lines, and the like are omitted.

As shown in FIG. 13, there are provided a device 121 which is a noise generation source, a device 122 which is susceptible to noise, an EBG structure 123, a ground line 124, an insulating substrate 125, a signal line 126, a printed wiring board 128, and a dielectric layer 129. The EBG structure 123 is fabricated on the insulating substrate 125. Specifically, as described above, the conductor pieces 12 are regularly arranged two-dimensionally on the insulating substrate 125. The dielectric layer 129, the interlayer insulating film 16, and the conductor plane 15 are sequentially stacked on the conductor pieces 12. The conductor pieces 12 and the conductor plane 15 are connected to each other with the connection conductors 14. The cover film 18 is formed on the conductor plane 15.

The conductor plane 15 of the EBG structure 123 is connected with the ground line 124 through a part of each of the connection conductors 14 and the conductor pieces 12. The cover film 18 has formed therein connecting portions 130 for mounting each of the device 121 which is a noise generation source and the device 122 which is susceptible to noise. The device 121 and the device 122 are mounted on the connecting portions 130. Referring to FIG. 13, one of the connecting portions of each of the devices 121 and 122 is connected to the signal line 126, and the other thereof is connected to the conductor plane 15. Further, a back side cover film 127 is formed below the insulating substrate 125.

In a lower part of the back side cover film 127, terminals for connecting with the printed wiring board 128 are formed. These terminals are mounted on the printed wiring board 128, thereby constituting a stacked multi-chip module. In the multi-chip module in which the EBG structure 123 is incorporated, the EBG structure can be downsized by applying the present invention. Consequently, the filter component can be disposed in proximity to the device 121, which is a noise generation source, within the package.

FIG. 14 is a cross-sectional view showing a structure of a filter component to which the present invention is applied and which is further thinned to have the advantage of being built in the substrate and which is formed into a film-like component suitable for being built in a flexible substrate. Referring to FIG. 14, the EBG structure is formed on a high heat-resistance polyimide resin 131.

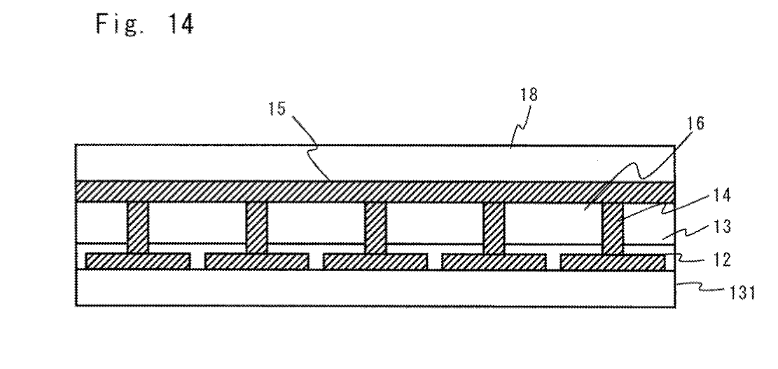

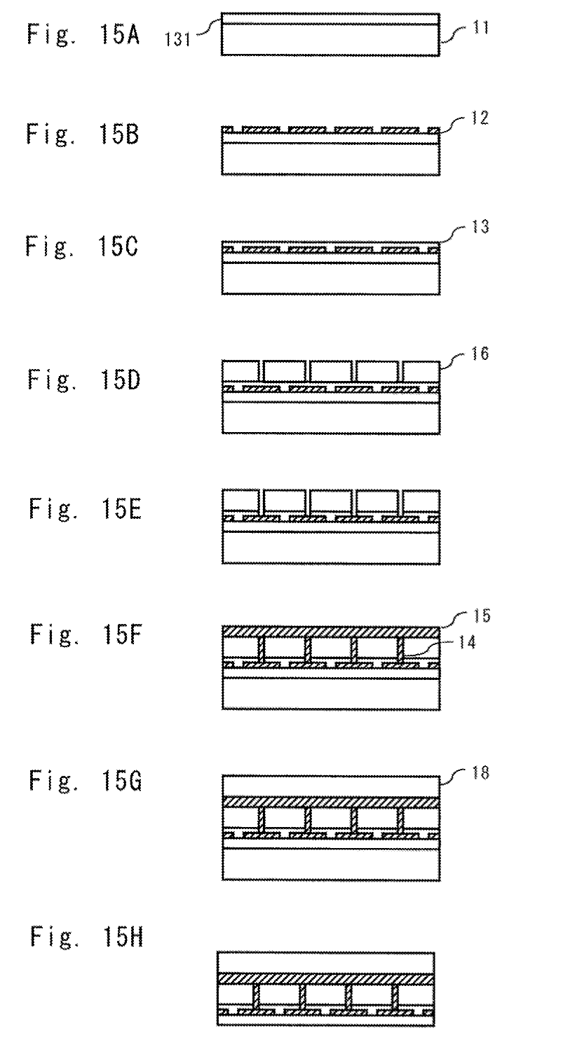

FIGS. 15A to 15H are production process cross-sectional views each illustrating a production method of a thin-film filter component to be built in the substrate to which the present invention is applied. After the heat-resistant polyimide resin is applied onto the insulating substrate 11 which is flat and has a heat resistance (FIG. 15A), the conductor pieces 12, the dielectric layer 13, the conductor plane 15, and the like are sequentially stacked (FIGS. 15B to 15G). Lastly, the insulating substrate 11 which is a rigid substrate is entirely removed by grinding or etching, thereby obtaining the film-like component the bottom surface of which is also covered with the resin (FIG. 15H).

As described above, according to the present invention, a high-dielectric-constant material can be directly deposited on the insulating substrate, which is flat and has a heat resistance, and on the conductor pieces at a high temperature of 300° C. or more by using a thin film forming method such as a sputtering method. Alternatively, conductor pieces can be buried in the high-dielectric-constant material itself. Accordingly, it is not necessary to reduce the effective dielectric constant by mixing a resin, so that the gap between the conductor pieces can be filled with a material with a high effective dielectric constant. This makes it possible to increase the capacitance per unit area between the conductor pieces, reduce the size of the conductor pieces, and lower the frequencies of band gaps. Further, the entire structure can be thinned by a thin film process and the capacitance per unit area can be increased. Consequently, the conductor pieces can be downsized even when the same capacity is required.

Having described the invention in connection with several embodiments, the present invention is not limited thereto. The structure and details of the present invention can be modified in various manners within the scope of the present invention as understood by those skilled in the art.

This application is based upon and claims the benefit of priority from Japanese patent application No. 2008-256970, filed on Oct. 2, 2008, the disclosure of which is incorporated herein in its entirety by reference.

### INDUSTRIAL APPLICABILITY

The present invention is applicable to an electromagnetic band gap structure having a band gap in a certain frequency band, an element using the same, a substrate, a module, a semiconductor device, and production methods thereof.

### REFERENCE SIGNS LIST

11, 125 INSULATING SUBSTRATE
12, 42 CONDUCTOR PIECE
13, 64, 129 DIELECTRIC LAYER
14, 63 CONNECTION CONDUCTOR
15 CONDUCTOR PLANE
16 INTERLAYER INSULATING FILM
17 CAPACITANCE ELEMENT
18 COVER FILM
19 OPENING
41 DIELECTRIC INSULATING SUBSTRATE
43, 65 CAPACITANCE ELEMENT
51 CAVITY
61 FIRST CONDUCTOR PIECE
62 SECOND CONDUCTOR PIECE
81 INDUCTANCE ELEMENT
91, 92 EXTERNAL CONNECTION TERMINAL
101, 121 DEVICE SERVING AS NOISE GENERATION SOURCE
102, 122 DEVICE SUSCEPTIBLE TO NOISE
103 COMMON MODE FILTER COMPONENT
104, 128 PRINTED WIRING BOARD
105 FIRST GROUND PLANE
106 SECOND GROUND PLANE
111 REMOVAL PORTION
123 EBG STRUCTURE
124 GROUND LINE
126 SIGNAL LINE
127 BACK SIDE COVER FILM
130 CONNECTING PORTION
131 HIGH HEAT-RESISTANCE POLYIMIDE RESIN

1. An electromagnetic band gap structure comprising:
an insulating substrate;
a plurality of conductor pieces regularly arranged on the insulating substrate;
a dielectric layer formed so as to fill a space between adjacent ones of the conductor pieces;
an interlayer insulating layer formed on the dielectric layer; and
a conductor plane that is formed on the interlayer insulating layer and is connected to each of the conductor pieces with a conductor penetrating through the interlayer insulating layer.

2. The electromagnetic band gap structure according to claim 1, wherein
the plurality of conductor pieces include a first conductor piece formed on the insulating substrate, and a second conductor piece formed above the first conductor piece, and
the dielectric layer is formed between the first conductor piece and the second conductor piece.

3. The electromagnetic band gap structure according to claim 2, wherein an interval between the first conductor piece and the second conductor piece is 1 μm or less.

4. The electromagnetic band gap structure according to claim 1, wherein the dielectric layer is stacked only in a space between adjacent ones of the conductor pieces in the same plane and in a neighboring region thereof.

5. The electromagnetic band gap structure according to claim 1, wherein the insulating substrate is made of a material selected from the group consisting of glass, alumina, sapphire, and quartz.

6. The electromagnetic band gap structure according to claim 1, wherein
the insulating substrate comprises the dielectric layer, and
the plurality of conductor pieces are buried in the insulating substrate.

7. The electromagnetic band gap structure according to claim 1, wherein each of the conductor pieces has a stacked structure of an intermediate layer which is formed of at least one layer selected from the group consisting of Ti, Ta, Cr, and nitrides of these elements and which is formed from a side of the insulating substrate, and at least one layer which is selected from the group consisting of Pt, Pd, Ru, and Ir and which is formed on an upper layer side of the intermediate layer.

8. The electromagnetic band gap structure according to claim 1, wherein the dielectric layer is mainly composed of at least one of oxides of Mg, Al, Si, Ti, Ta, Hf, and Zr.

9. The electromagnetic band gap structure according to claim 1, wherein the dielectric layer is mainly composed of a material comprising a composite oxide represented by a chemical formula ABO₃ or A₂B₂O₇ as a basic structure.

10. A filter element comprising:
an electromagnetic band gap structure according to claim 1; and
an external connection terminal formed on a part of the conductor plane.

11. An antenna element comprising:
an electromagnetic band gap structure according to claim 1; and
a feeder connected to a part of the conductor plane.

12. A substrate with a built-in element comprising:
a printed wiring board; and
at least one of an electromagnetic band gap structure according to claim 1, the electromagnetic band gap structure being buried in the printed wiring board, a filter element according to claim 10, and an antenna element according to claim 11.

13. A multi-chip module comprising:
a substrate with a built-in element according to claim 12; and
two or more semiconductor devices mounted on the substrate with a built-in element.

14. A semiconductor device comprising:
an electromagnetic band gap structure according to claim 1; and
one or more semiconductor elements mounted in the electromagnetic band gap structure.

15. A multi-chip module comprising:
a semiconductor device according to claim 14;
two or more semiconductor elements mounted on the semiconductor device; and
a terminal that is formed on the semiconductor element and is connected to another printed wiring board.

16. A production method of an electromagnetic band gap structure, comprising:
forming a plurality of conductor pieces regularly on an insulating substrate;
forming a dielectric layer so as to fill a space between adjacent ones of the conductor pieces;
forming an interlayer insulating layer on the dielectric layer; and
forming a conductor plane on the interlayer insulating layer, the conductor plane being connected to each of the conductor pieces.

17. The production method of an electromagnetic band gap substrate according to claim 16, wherein after the formation of the dielectric layer, a portion of the dielectric layer other than portions formed in a space between adjacent ones of the conductor pieces in the same plane and in a neighboring region thereof is removed.

18. The production method of an electromagnetic band gap structure according to claim 16, wherein, in the step of forming the dielectric layer, the dielectric layer is stacked with a portion of the dielectric layer other than portions formed in a space between adjacent ones of the conductor pieces in the same plane and in a neighboring region thereof as a mask.

19. The production method of an electromagnetic band gap structure according to claim 16, comprising:
forming, as the plurality of conductor pieces, a first conductor piece and a second conductor piece above the first conductor piece; and
forming the dielectric layer between the first conductor piece and the second conductor piece.

20. The production method of an electromagnetic band gap structure according to claim 19, wherein the dielectric layer has a thickness of 1 μm or less.

21. The production method of an electromagnetic band gap structure according to claim 16, wherein
the insulating substrate comprises the dielectric layer, and
the plurality of conductor pieces are buried in the insulating substrate to thereby form the dielectric layer between adjacent ones of the conductor pieces.

22. The production method of an electromagnetic band gap structure according to claim 16, wherein the step of forming the conductor pieces comprises:
forming an intermediate layer which is formed of at least one layer selected from the group consisting of Ti, Ta, Cr, and nitrides of these elements and which is formed from a side of the insulating substrate; and
stacking at least one layer selected from the group consisting of Pt, Pd, Ru;
and Ir on an upper layer side of the intermediate layer.

23. The production method of an electromagnetic band gap structure according to claim 16, wherein the dielectric layer is mainly composed of at least one of oxides and nitrides of Mg, Al, Si, Ti, Ta, Hf, and Zr.

24. The production method of an electromagnetic band gap structure according to claim 16, wherein the dielectric layer is mainly composed of a material comprising a composite oxide represented by a chemical formula ABO₃ or A₂B₂O₇ as a basic structure.

25. The electromagnetic band gap structure according to claim 16, wherein the dielectric layer is deposited by a method selected from the group consisting of a sputtering method, a CVD method, a sol-gel method, and an aerosol deposition method.

26. The production method of an electromagnetic band gap structure according to claim 16, wherein the insulating substrate is made of a material selected from the group consisting of glass, alumina, sapphire, and quartz.

27. The production method of an electromagnetic band gap structure according to claim 16, wherein the insulating substrate is thinned after formation of a stacked structure of the plurality of conductor pieces, the dielectric layer, the interlayer insulating layer, and the conductor plane.

28. The production method of an electromagnetic band gap structure according to claim 16, wherein
the insulating substrate is a structure in which a polyimide resin is applied onto a surface of a plate-like base material selected from the group consisting of glass, alumina, sapphire, quartz, silicon, GaAs, stainless steel, Cu, Ni, W, and Mo, and
the plate-like base material is removed after formation of a stacked structure of the plurality of conductor pieces, the dielectric layer, the interlayer insulating layer, and the conductor plane.

29. A production method of a substrate with a built-in element, a multi-chip module, or a semiconductor device, comprising:
forming an electromagnetic band gap structure on an insulating substrate by a production method according to claim 16;
thinning or removing the insulating substrate so that a structure having the electromagnetic band gap structure formed on the insulating substrate has an overall thickness of 300 μm or less; and
burying the thinned structure in a printed wiring board.
